(19) United States
(12) Patent Application Publication
(10) Pub. No.: US 2024/0346221 A1
(43) Pub. Date: Oct. 17, 2024

(54) CIRCUITS AND METHODS FOR REDUCING THE EFFECTS OF VARIATION IN INTER-DIE COMMUNICATION IN 3D-STACKED SYSTEMS

(71) Applicant: Meta Platforms Technologies, LLC, Menlo Park, CA (US)

(72) Inventors: Matheus Trevisan Moreira, La Jolla, CA (US); Edith Dallard, San Mateo, CA (US); Huseyin Ekin Sumbul, San Francisco, CA (US); Fan Wu, Redwood City, CA (US); William Koven, San Jose, CA (US)

(21) Appl. No.: 18/436,602

(22) Filed: Feb. 8, 2024

Related U.S. Application Data
(60) Provisional application No. 63/483,956, filed on Feb. 8, 2023.

(51) Int. Cl. G06F 30/35; G06F 5/06; G06F 30/347

(52) U.S. Cl. CPC G06F 30/35; G06F 5/06; G06F 30/347

(57) ABSTRACT

A device for reducing the effects of variation in inter-die communication in 3D-stacked systems may include a die-to-die interconnect that includes a first module configured to convert data from a first synchronous domain to a dual-rail quasi-delay-insensitive format and a second module configured to convert the data from the dual-rail quasi-delay-insensitive format to a second synchronous domain. Various other devices, systems, and methods of manufacture are also disclosed.

### RELATED APPLICATION DATA

This application claims the benefit of U.S. Application No. 63/483,956, filed 8 Feb. 2023, the disclosure of which is incorporated, in its entirety, by this reference.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a diagram of an exemplary architecture of a quasi-delay-insensitive interconnect.

FIG. 2 is a diagram of an exemplary weak-conditioned half buffer.

FIG. 3 is a diagram of an exemplary C-element schematic.

FIG. 4 is a diagram of an exemplary queue and quasi-delay-insensitive transmission interface.

FIG. 5 is a diagram of an exemplary clock control for a quasi-delay-insensitive system.

FIGS. 6A and 6B are diagrams of exemplary quasi-delay-insensitive transmission converter and WPointer logic, respectively.

FIG. 7 is a diagram of exemplary quasi-delay-insensitive transmission RPointer logic.

FIG. 8 is a diagram of an exemplary queue and quasi-delay-insensitive reception interface.

FIGS. 9A and 9B are diagrams of exemplary quasi-delay-insensitive reception WPointer and RPointer logic, respectively.

FIG. 10 is a flow diagram of an exemplary method for reducing the effects of variation inter-die communication in 3D-stacked systems.

FIG. 11 is a diagram of an exemplary method of manufacture for a quasi-delay-insensitive interconnect.

FIG. 12 is an illustration of exemplary augmented-reality glasses that may be used in connection with embodiments of this disclosure.

FIG. 13 is an illustration of an exemplary virtual-reality headset that may be used in connection with embodiments of this disclosure.

FIG. 14 is an illustration of exemplary haptic devices that may be used in connection with embodiments of this disclosure.

FIG. 15 is an illustration of an exemplary virtual-reality environment according to embodiments of this disclosure.

FIG. 16 is an illustration of an exemplary augmented-reality environment according to embodiments of this disclosure.

FIG. 17 an illustration of an exemplary system that incorporates an eye-tracking subsystem capable of tracking a user's eye(s).

FIG. 18 is a more detailed illustration of various aspects of the eye-tracking subsystem illustrated in FIG. 17.

FIGS. 19A and 19B are illustrations of an exemplary human-machine interface configured to be worn around a user's lower arm or wrist.

FIGS. 20A and 20B are illustrations of an exemplary schematic diagram with internal components of a wearable system.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and appendix and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXAMPLE EMBODIMENTS

Integrated circuits may face delay variations from different sources, including process, temperature and voltage. Typically, timing margins are added to synchronous designs to account for such variations, at the expense of reduced performance and increased power and area. These overheads are, at many times, acceptable in single die designs, because a single die is mostly affected by local variations within the die. However, in 3D stacked systems, the problem can be significantly exacerbated if dies of different wafers are stacked together, as different wafers will present global variations that are larger than local ones, which is the case for some 3D integration processes. This is particularly aggravated in heterogeneous stacking, when the wafers are from different technology process nodes. Hence, such 3D stacked systems may need significant overheads in the added margins, which may not even be feasible depending on global variations.

The present disclosure is generally directed to a quasi-delay-insensitive circuit that may be used to create a point-to-point communication channel for connecting dies in 3D-stacked systems. In some examples, one or more of the disclosed circuits may be, by construction, robust to delay variations and may tolerate the large global variations incurred in 3D-stacked systems. In some examples, one or more of the disclosed circuits may consist of a transmitter and a receiver that may go in different dies and may be compatible with any system-on-chip (SoC) protocol that allows back-pressure control or credit-based operation. The disclosed systems may use quasi-delay-insensitive logic for inter-die communication rather than traditional synchronous designs. In some examples, a chip may count with one or more of the disclosed circuits.

In the circuit design described in greater detail below, a quasi-delay-insensitive (QDI) design may offer robustness to delay variations in interconnects crossing between dies. In addition, rather than relying on through silicon via (TSV) processes, where the density of interconnects is reduced due to the larger pitch required between TSVs, the devices and systems described herein may provide high-density and high-performance interconnects using a hybrid bonding (HB) process. Thus, for example, systems described herein include a QDI interconnect suitable for a D2D interface in an artificial intelligence (AI) multi-die system for embedded applications. In some embodiments, the design may be fully implemented using traditional standard cell libraries and electronic design automation (EDA) tools.

As used herein, the term “delay-insensitive” (DI) as it applies to circuits generally refers to any circuit that works correctly even when a signal in the circuit is delayed (e.g., due to environmental factors such as variations in temperature and/or voltage; due to physical factors caused by processing imperfections, etc.). As used herein, the term “quasi-delay-insensitive” (QDI) may generally refer to any circuit that demonstrates delay insensitivity under specified assumptions. For example, the term “quasi-delay-insensitive” may refer to a circuit that is delay-insensitive (e.g., the circuit works correctly regardless of the values of the delays in the gates and wires of the circuit) under the assumption that one or more wire forks are isochronic. As used herein, the term “isochronic” as it relates to wire forks may refer to any wire fork where the difference in the times at which a signal arrives at the ends of the fork is less than the minimum gate delay.

As used herein, the term “dual-rail” as it relates to circuits may generally refer to a circuit where a bit signal is carried on two wires instead of one. For example, one wire may indicate whether or not the bit value is 1, and the other wire may indicate whether or not the bit value is 0. Thus, for example, a dual-rail bit signal may also indicate the presence or absence of data. For example, the dual-rail bit signal may indicate the presence of data by indicating the value of 1 or the value of 0, and may indicate the absence of data by indicating neither the value of 1 nor the value of 0. As may be appreciated, a dual-rail encoding may facilitate a handshaking mechanism for a QDI circuit by indicating the presence or absence of data and, thereby, ensuring that each operation completes before the next begins.

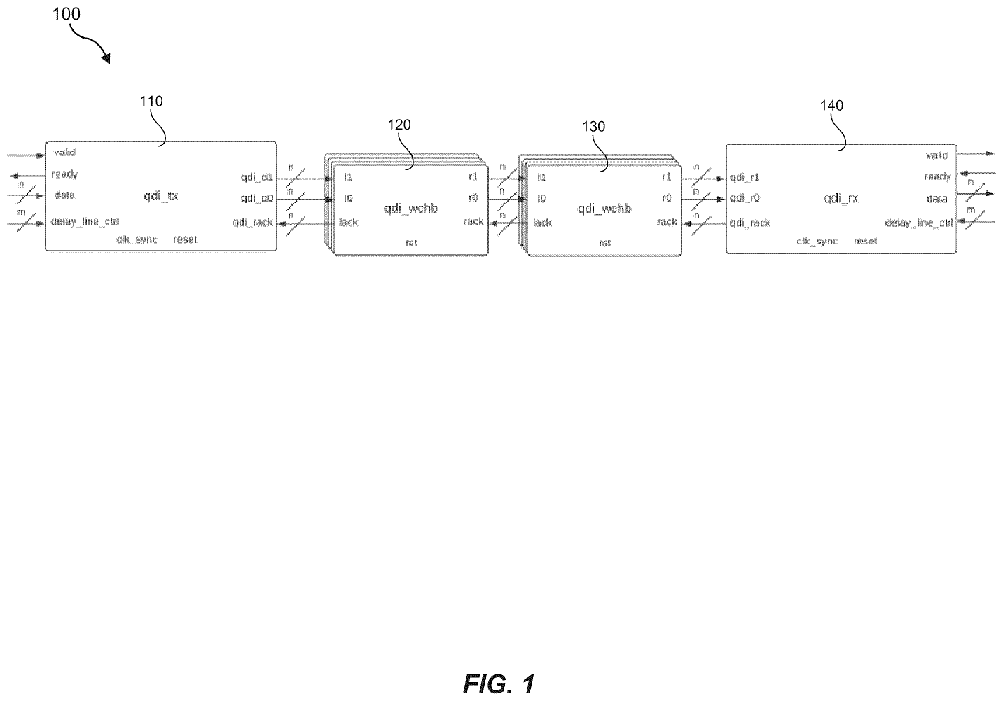

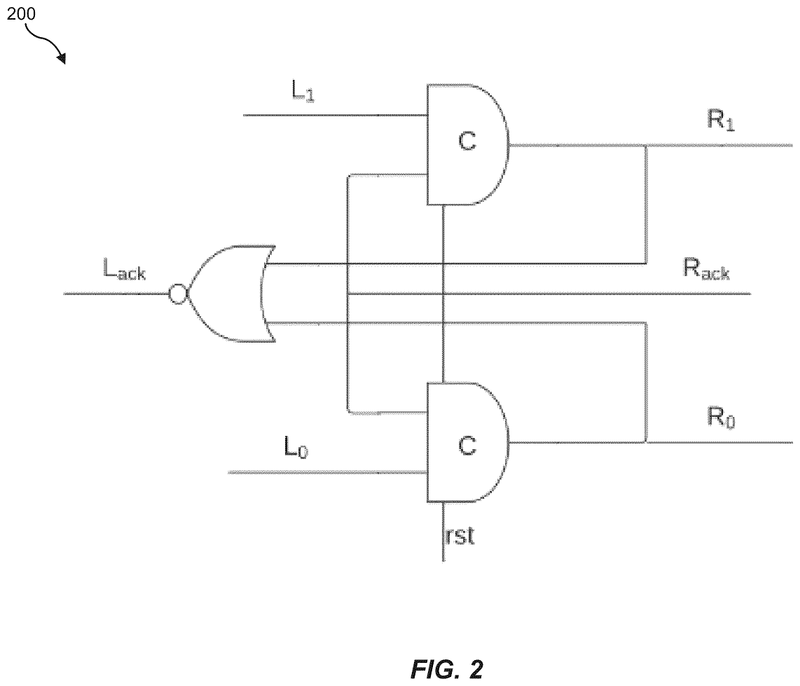

FIG. 1 shows a QDI interconnect 100. As illustrated in FIG. 1, in one embodiment QDI interconnect 100 may include three main blocks: a Sync-to-QDI block 110, a WCHB pipeline (e.g., including a set of WCHBs 120 and a set of WCHBs 130), and a QDI-to-Sync block 140. Sync-to-QDI block 110 interfaces with a transmitter block (not pictured) and may include a valid/ready input interface and a data bus of n bits (valid, ready and data). The output of the Sync-to-QDI block 110 may include a 4-phase dual-rail (DR) delay-insensitive (DI) interface of n bits (r1, r0 and r_{ack}). Additionally, the Sync-to-QDI block 110 may have a clock signal (clk) connected to the synchronous clock of the transmitter block, a reset signal (rst) and an m-bit control bus for internal registers configuration and DFT (ctrl) that is synchronous to clk. The Sync-to-QDI block 110 is responsible for reading synchronous data from the valid/ready interface, converting it to DR and transmitting it through the DI interface. To do so, the Sync-to-QDI block 110 may use an internal bi-synchronous FIFO, a synchronous-to-QDI converter, and a layer of n weak-conditioned half buffers (WCHBs), such as weak-conditioned half buffer 200 illustrated in FIG. 2.

In some embodiments, FIFO data write may be performed using the synchronous clock and data read using a clock generated from the acknowledge signals of the DI interface. The converter may read data from the FIFO and write the data to the WCHB layer using the handshake protocol, both generating spacers and popping data from the FIFO. The WCHB layer transmits the data to the output DI interface, which is connected to a WCHB Pipeline of two stages (set of WCHBs 120 and set of WCHBs 130), each stage with n WCHB blocks.

The output of the WCHB Pipeline is connected to QDI-to-Sync block 140, which interfaces with a receiver block (not pictured). The QDI-to-Sync block 140 may include a 4-phase DR DI interface of n bits (l1, l0 and l_{ack}) and an n-bit valid/ready output interface (valid, ready and data). The QDI-to-Sync block 140 may also include a clock signal (clk) connected to the synchronous clock of the receiver block, a reset signal (rst) and an m-bit control bus for internal registers configuration and DFT (ctrl) that is synchronous to clk. The QDI-to-Sync block 140 may be responsible for reading data from the DI interface, converting to single rail and transmitting the data through the valid/ready output interface. To do so, the QDI-to-Sync block 140 may include a layer of n WCHBs, a bi-synchronous FIFO and a QDI-to-synchronous converter. The layer of WCHBs reads data from the DI input interface and writes the data to the FIFO using a clock generated from the data signals of the DI interface. The converter reads data from the FIFO using the synchronous clock using the read pointer and writes it to the valid/ready interface, popping it from the FIFO when the data is consumed by the interface.

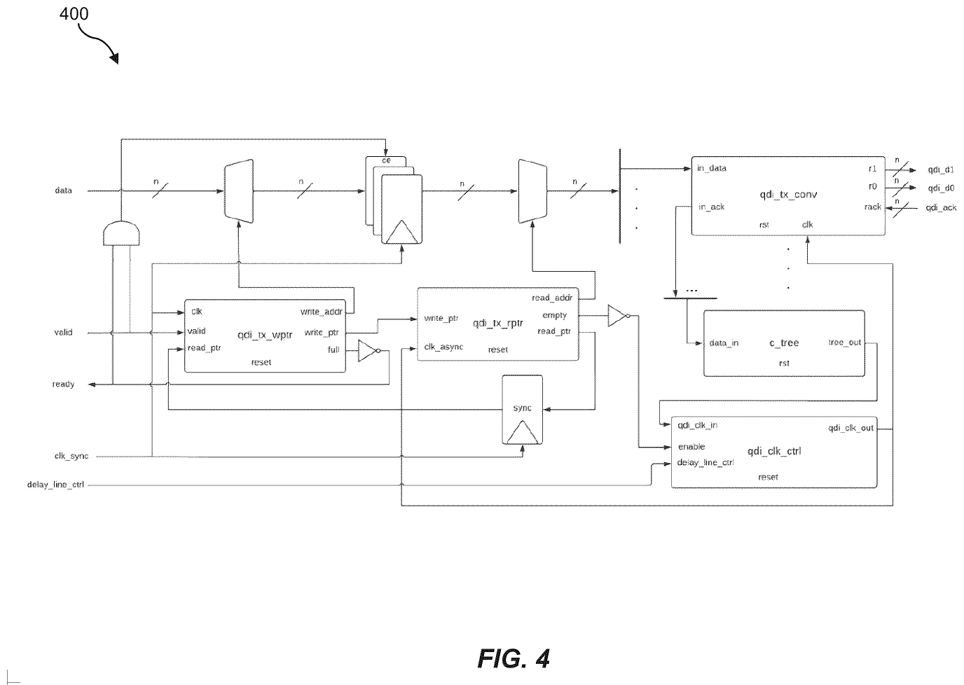

FIG. 4 is an illustration of an exemplary circuit 400 providing a FIFO and QDI interface for transmission. In one embodiment, a QDI interface for transmission may be configured such that at reset, all blocks are reset and spacers are injected to QDI interface. In one example, FIFO will be empty and ready to receive data and clock control (qdi_clk_ctrl) will be ready to trigger clock out when enable and ack signals arrive. In one embodiment, FIFO will buffer data and implement synchronous valid/ready protocol. In this embodiment, the interface will always ready while FIFO is not full. In some implementations, the design may use Valid/Ready back pressure control using FIFO's “full” state, a “QDI clock” generated to consume data from FIFO and inject data to the QDI domain, and/or a synchronizer to avoid metastability issues with synchronous interfaces.

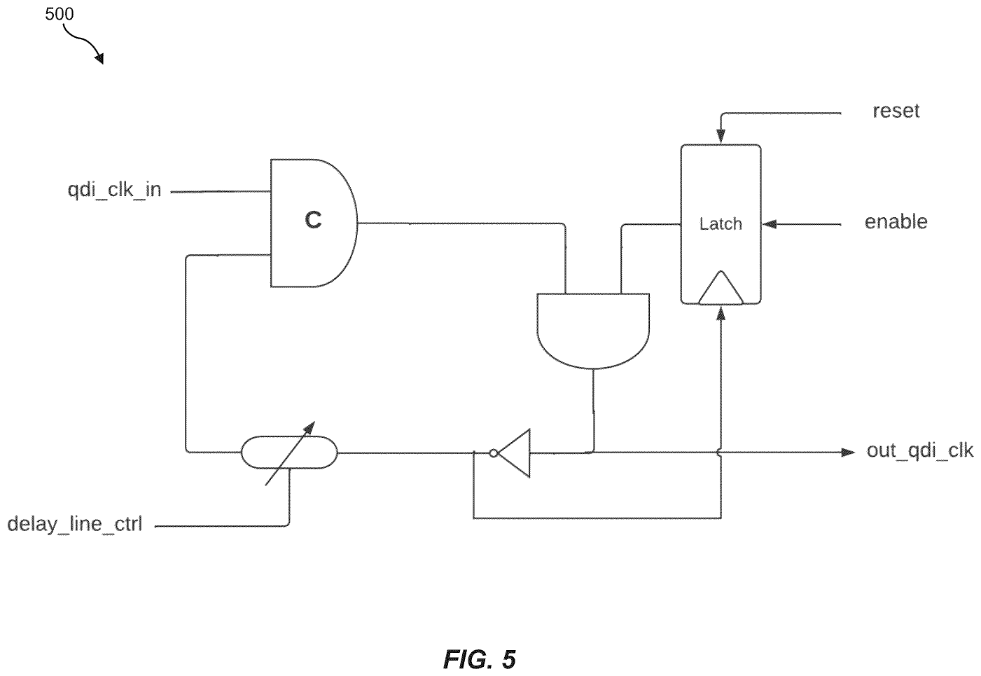

In some examples, as illustrated in FIG. 5, the interface may include a circuit 500 implementing an input clock generated by ack signals. In one embodiment, the systems described herein may include a programmable delay line to create a programmable clock. In some embodiments, this may default to the slowest clock, have margin control for performance optimization, and/or allow for controlling a minimum clock period.

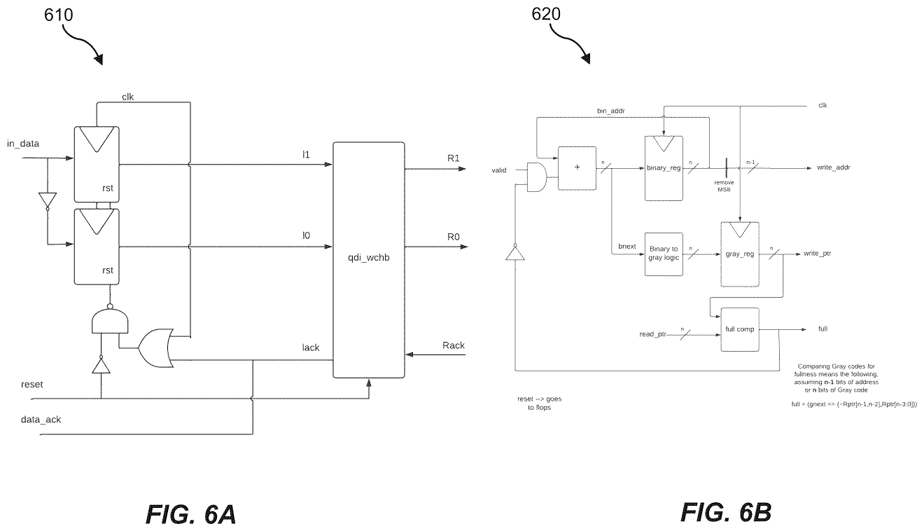

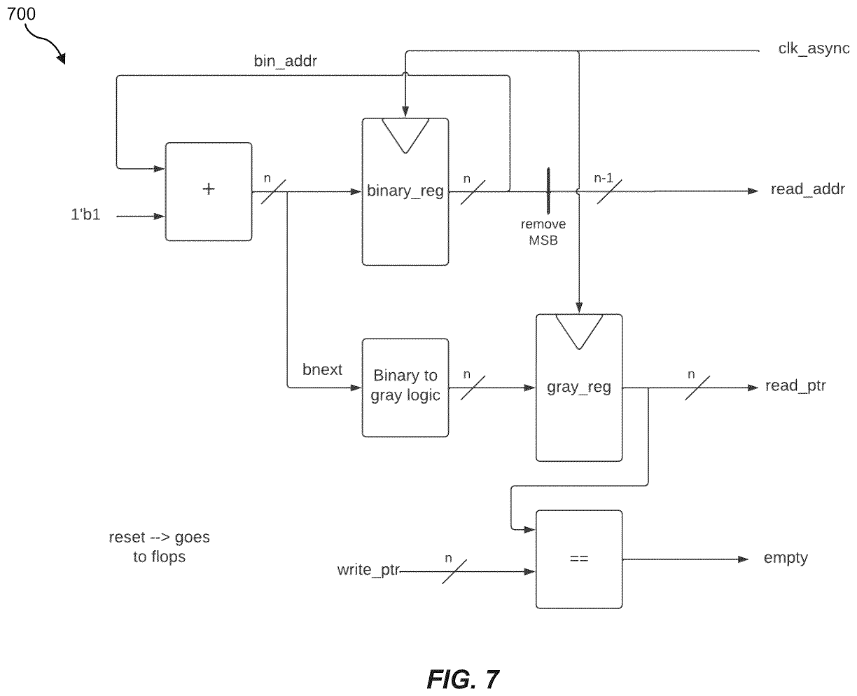

In some examples, as is illustrated by an example circuit 610 in FIG. 6A, data may be read at clk, the data flows to a WCHB (e.g., a full token can be held at the converter), and ack/clk reset flops to generate a spacer. In some embodiments, there may be timing constraints for rst and/or clk. In one embodiment, as illustrated by an example circuit 620 in FIG. 6B, a read_ptr may be synchronized to clk to safely sample the “full” state. In some embodiments, circuit 620 may use a gray code encoding to minimize risk of error. In one embodiment, as illustrated in FIG. 7, device 700 may be configured such that async write_ptr can only cause “not empty,” “not empty” is what triggers clk_async, and/or a minimum period of “QDI clock” is guaranteed by qdi_clk_ctrl. In some examples, this configuration may avoid glitches, control minimum pulse width, and/or be configured such that empty is controlled by clk_async to enable stable operation.

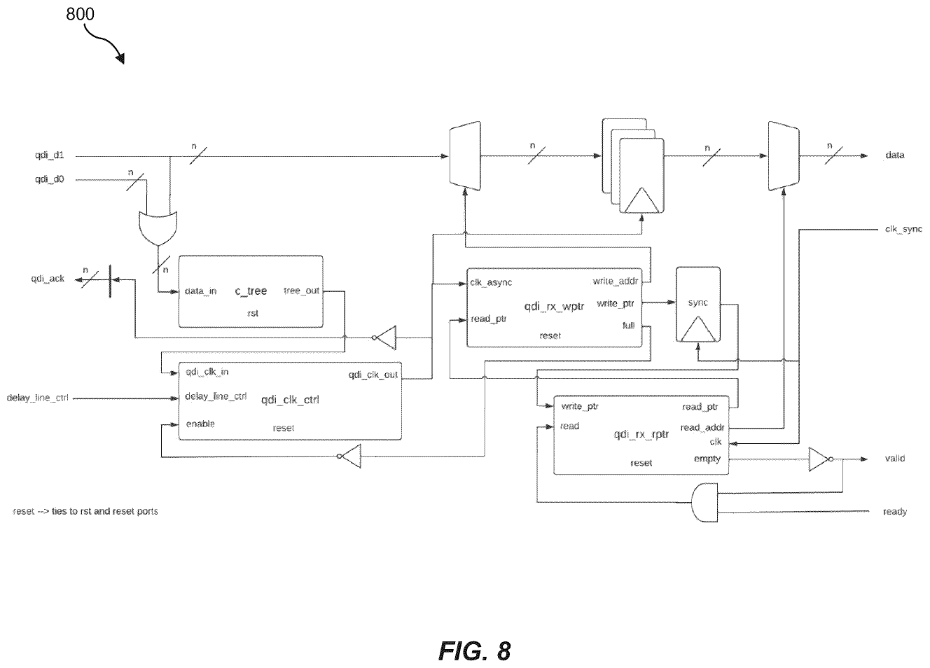

FIG. 8 is a diagram of an example circuit 800 implementing an exemplary FIFO and quasi-delay-insensitive reception interface. In one embodiment, at reset, blocks are reset and QDI ack signals are all 1s. In this example, FIFO will be empty and ready to receive data and clock control will be ready to trigger clock out when enable and ack signals arrive. In one embodiment, a “QDI clock” may be generated to acknowledge data and spacer from the QDI domain. In some examples, the “QDI clock” may also be used to inject data to FIFO. In some embodiments, the interface may include a synchronizer to avoid metastability issues with synchronous interfaces and/or a FIFO to buffer data and implement synchronous Valid/Ready protocol.

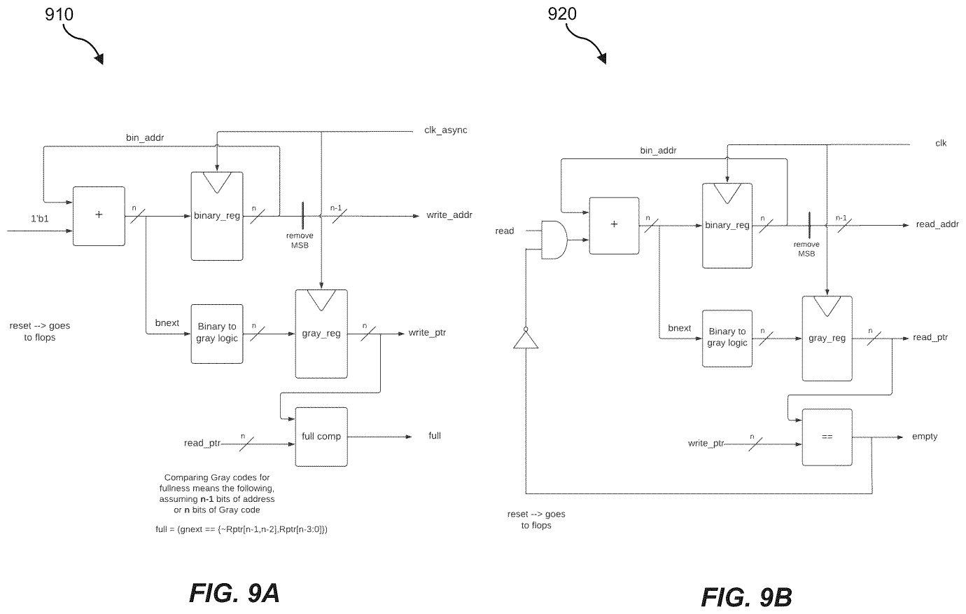

FIG. 9A illustrates an example circuit 910 implementing an exemplary WPointer logic for a QDI reception interface. In some embodiments, one or more of the elements of circuit 910 \may be configured to use gray code to minimize the risk of error during the transition between values (e.g., as only one bit changes at a time). In one embodiment, the async read_ptr can only cause “full.” In some embodiments, “full” may gate clk_async. In some embodiments, the systems described herein may be configured with a minimum period of “QDI clock” guaranteed by qdi_clk_ctrl that avoids glitches, controls minimum pulse width, and/or is configured such that full is controlled by clk_async to enable stable operation. Similarly, an example circuit 920 implementing RPointer logic as illustrated in FIG. 9B may use gray code to reduce the risk of error. In some embodiments, read_ptr may be synchronized to clock to safely sample “empty.”

In some examples, the valid/ready interfaces of the Sync-to-QDI 110 and QDI-to-Sync 140 blocks of FIG. 1 may allow for flexible integration with different system-on-chip (SoC) protocols. In some examples, the devices described herein may be compatible with the Open Core Protocol (OCP) and/or with any protocol that allows for flow control. The size of the FIFOs of the Sync-to-QDI 110 and QDI-to-Sync 140 blocks is a function of the operating frequencies of the transmitter and receiver blocks and traffic patterns. In addition, in some examples, these busses may have completely unrelated clocks. As FIG. 1 shows, hybrid bonding takes place in the signals between set of WCHBs 120 and set of WCHBs 130 of the WCHB Pipeline. Hence, the only signals that cross from one die to another are those of the DI interfaces attached to the WCHBs, allowing the design to leverage the robustness of DI for the D2D interconnects.

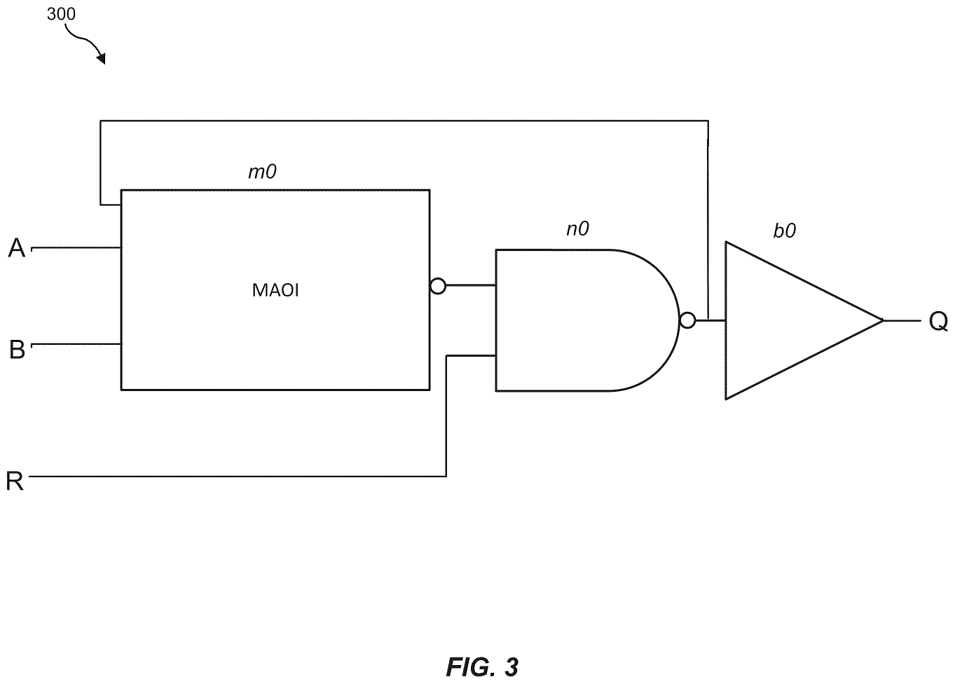

In some examples, the number of stages in the WCHB pipeline may be a function of the distance that must be travelled from the Sync-to-QDI 110 and QDI-to-Sync 140 blocks to the hybrid bumps and the desired cycle time (CT) of the circuit. As may be appreciated, the QDI circuit may include C-elements in its design. In some examples, to comply with a fully standard-cell-based design, such components may be mapped to a combination of a majority and-or-invert gate, a nor gate and an output buffer, an example of which is shown with a circuit 300 in FIG. 3. Thus, for examples, gates may be used that are typically available in traditional standard-cell libraries and allow the design of a resettable C-element.

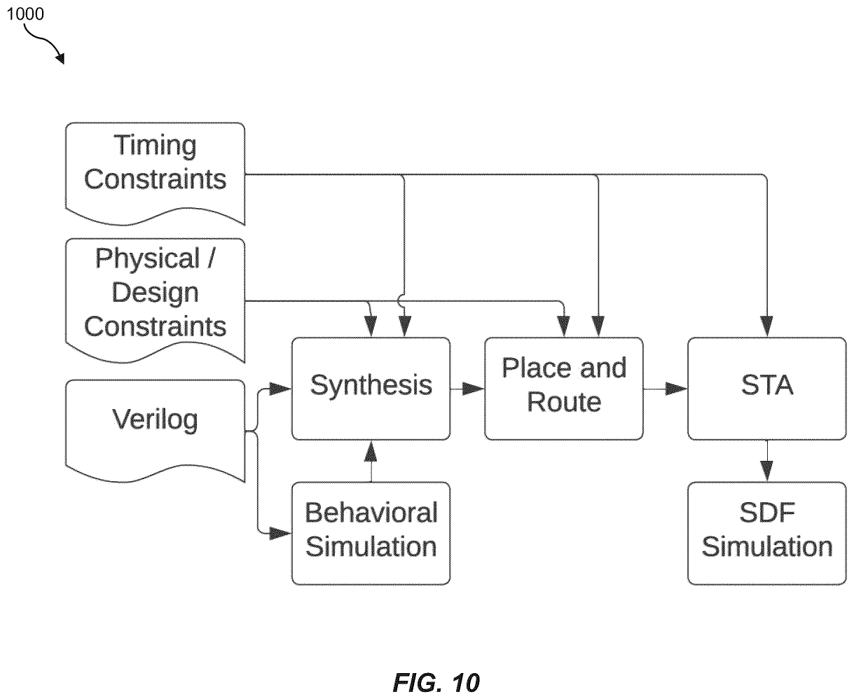

FIG. 10 illustrates a design flow 1000 used to implement the QDI interconnect. In some examples, the circuit may be described using synthesizable Verilog for the synchronous portions of the design and structural Verilog for the QDI portions. This description may include pound delays for behavioral simulation to verify functionality. Next, physical aware synthesis is performed using this Verilog as input along with a set of constraints. Design constraints are used to declare don't touch and size only statements to prevent implementation tools from optimizing QDI portions of the design. Physical constraints may be used to define fences so that the placement of the gates that compose C-elements is bounded. This may allow for better control of the delay of the internal signals of C-element components. Finally, timing constraints are used to define a clock for the synchronous portions of the design and to model CT and relative timing constraints (RTCs) for the QDI portions. The former is defined in a functional mode, where there are no valid paths in the QDI logic. CT and RTCs are modeled using different modes.

Because the QDI circuit consists of a linear WCHB-based pipeline, CT constraints are defined using max delay statements between the output of C-elements. In CT modes, the path of the internal loop of C-elements is disabled. For RTCs, a combination of max delay and min delay statements are used. Special care is taken for modeling the timing of C-elements, since they are abundant in the QDI circuit. Returning to FIG. 3, a max delay statement was defined from the output of gate no to the input of gate m0 and a min delay statement was defined from the output of gate no to the input of the output of gate b0. This ensures that the internal loop always stabilizes before a new input is received. Also, paths from the inputs of the C-element to gate m0 were disabled, to break combinational loops present in the WCHB pipeline.

In some embodiments, this set of constraints is enough to allow EDA tools to correctly analyze the circuit using traditional static timing analysis (STA), since the combination of min delay, max delay and disabling paths allow for an acyclic graph, and optimize it to the target timing. After synthesis, the circuit proceeds to place and route, followed by STA. The latter flags potential hazards in RTC modes and performance in CT modes. In single-die STA, all setup and hold corners must be checked, as RTC modes rely on both max delay and min delay constraints. However, in multi-die STA, only setup corners are required, since there are no RTCs in a DI interface. From STA, it is possible to export Standard Delay Format (SDF) files with delay annotation for different corners, along with the implemented netlist, for a final verification in SDF simulation.

In some embodiments, the QDI interconnect may be fully implemented with industry standard EDA and standard-cell libraries. STA shows that the required timing is achieved and SDF simulation demonstrates correct functionality with a throughput that complies with the specified CT. Compared to synchronous equivalent D2D interfaces, it requires only 25% of multi-die STA corners, as they are dominated by hold checks. Furthermore, the clock tree is significantly less complex, as the clocks of transmitter and receiver blocks can be completely asynchronous to each other. When the D2D interface is active, the power considering the QDI interconnect and associated SoC logic to access the interface of transmitter and receiver blocks may be approximately 72 mW and the power of the QDI interconnect in isolation may be approximately 3.3 mW at 0.75V and 25° C. In some examples, this circuit consumes only a fraction of the overall power. Therefore, this application can tolerate the power overheads typically attributed to QDI design, while leveraging the robustness benefits it allows. Compared to alternative implementations, this design leverages the high density and performance of HB to provide a way to interconnect dies in a 3D system, demonstrating the potential benefits of using QDI for D2D interfaces for embedded and AI applications.

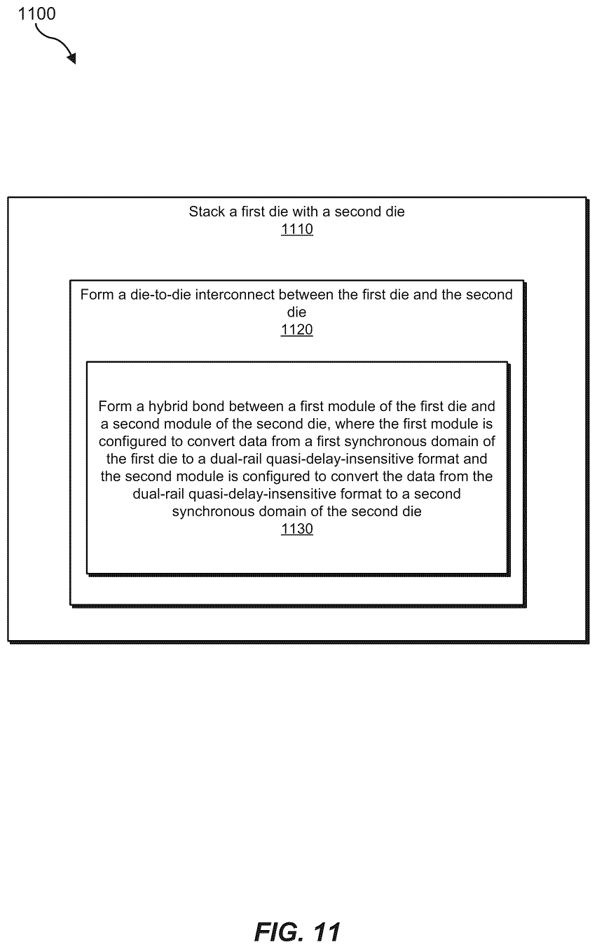

FIG. 11 is a diagram of an exemplary method of manufacture 1100 for a quasi-delay-insensitive interconnect. As shown in FIG. 11, method of manufacture 1100 may include a step 1110 of stacking a first die with a second die (e.g., resulting in a 3D architecture). As a part of step 1110, method of manufacture 1100 may include a step 1120 of forming a die-to-die interconnect between the first die and the second die (e.g., a QDI interconnect). As a part of step 1120, method of manufacture 1100 may include a step 1130 of forming a hybrid bond between a first module of the first die and a second module of the second die. The first module may be configured to convert data from a first synchronous domain of the first die to a dual-rail quasi-delay-insensitive format and the second module may be configured to convert the data from the dual-rail quasi-delay-insensitive format to a second synchronous domain of the second die.

In one example, a device may include a die-to-die interconnect including a first module configured to convert data from a first synchronous domain to a dual-rail quasi-delay-insensitive format and a second module configured to convert the data from the dual-rail quasi-delay-insensitive format to a second synchronous domain.

In one example, the first module and the second module may be coupled by hybrid bonding.

In one example, the first module may include a first bisynchronous First-In First-Out (FIFO) buffer, a first weak-conditioned half-buffer (WCHB) layer, and a first converter configured to read from the first bisynchronous FIFO buffer and write to the first WCHB layer.

In one example, the first bisynchronous FIFO buffer may be configured to be written to according to a clock of the first synchronous domain and be read from based on an acknowledgement signal from the first WCHB layer.

In one example, the first module the first module may receive the data via an n-bit bus and the first WCHB layer may include n WCHBs operating in parallel.

In one example, the first converter may be configured to pop the data from the first FIFO buffer when the data is consumed.

In one example, the second module may include a second WCHB layer, a second bisynchronous FIFO buffer, and a second converter configured to read from the second WCHB layer and write to the second FIFO buffer.

In one example, the second bisynchronous FIFO buffer may be configured to be written to based on an acknowledgement signal from the second WCHB layer and be read from according to a clock of the second synchronous domain.

In one example, the second module may provide the data via an n-bit bus and the second WCHB layer may include n WCHBs operating in parallel.

In one example, the first synchronous domain and the second synchronous domain may be the same domain.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

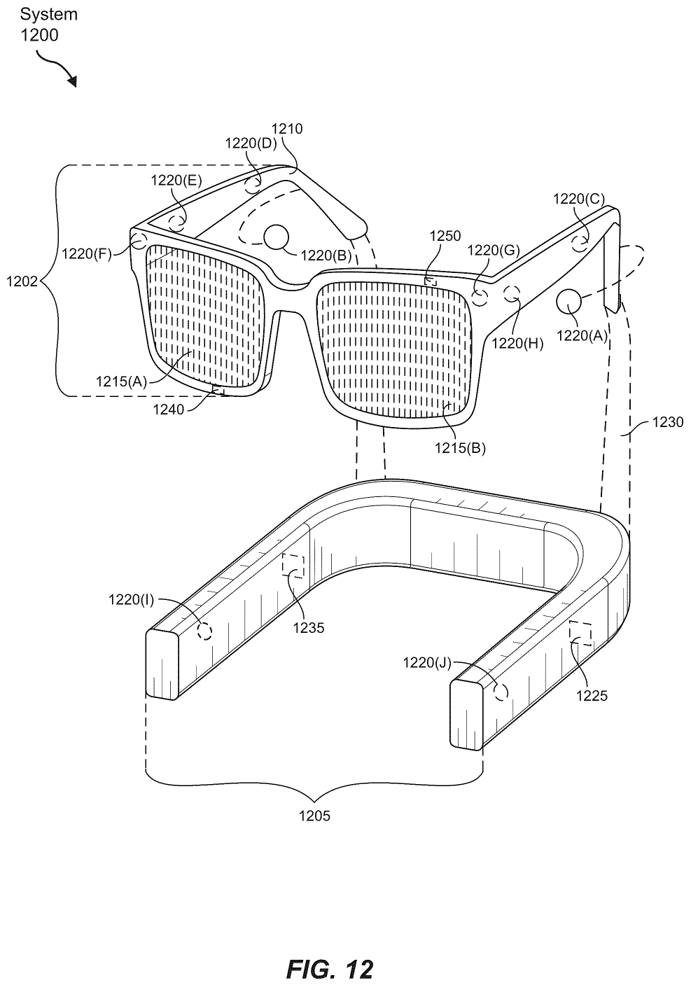

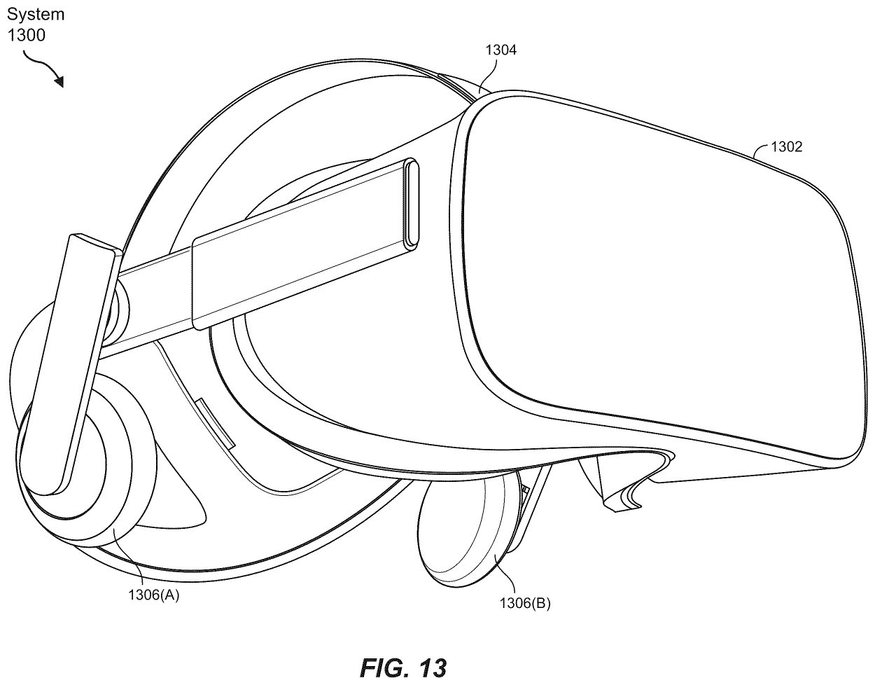

Artificial-reality systems may be implemented in a variety of different form factors and configurations. Some artificial-reality systems may be designed to work without near-eye displays (NEDs). Other artificial-reality systems may include an NED that also provides visibility into the real world (such as, e.g., augmented-reality system 1200 in FIG. 12) or that visually immerses a user in an artificial reality (such as, e.g., virtual-reality system 1300 in FIG. 13). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 12, augmented-reality system 1200 may include an eyewear device 1202 with a frame 1210 configured to hold a left display device 1215(A) and a right display device 1215(B) in front of a user's eyes. Display devices 1215(A) and 1215(B) may act together or independently to present an image or series of images to a user. While augmented-reality system 1200 includes two displays, embodiments of this disclosure may be implemented in augmented-reality systems with a single NED or more than two NEDs.

In some embodiments, augmented-reality system 1200 may include one or more sensors, such as sensor 1240. Sensor 1240 may generate measurement signals in response to motion of augmented-reality system 1200 and may be located on substantially any portion of frame 1210. Sensor 1240 may represent one or more of a variety of different sensing mechanisms, such as a position sensor, an inertial measurement unit (IMU), a depth camera assembly, a structured light emitter and/or detector, or any combination thereof. In some embodiments, augmented-reality system 1200 may or may not include sensor 1240 or may include more than one sensor. In embodiments in which sensor 1240 includes an IMU, the IMU may generate calibration data based on measurement signals from sensor 1240. Examples of sensor 1240 may include, without limitation, accelerometers, gyroscopes, magnetometers, other suitable types of sensors that detect motion, sensors used for error correction of the IMU, or some combination thereof.

In some examples, augmented-reality system 1200 may also include a microphone array with a plurality of acoustic transducers 1220(A)-1220(J), referred to collectively as acoustic transducers 1220. Acoustic transducers 1220 may represent transducers that detect air pressure variations induced by sound waves. Each acoustic transducer 1220 may be configured to detect sound and convert the detected sound into an electronic format (e.g., an analog or digital format). The microphone array in FIG. 12 may include, for example, ten acoustic transducers: 1220(A) and 1220(B), which may be designed to be placed inside a corresponding ear of the user, acoustic transducers 1220(C), 1220(D), 1220(E), 1220(F), 1220(G), and 1220(H), which may be positioned at various locations on frame 1210, and/or acoustic transducers 1220(I) and 1220(J), which may be positioned on a corresponding neckband 1205.

In some embodiments, one or more of acoustic transducers 1220(A)-(J) may be used as output transducers (e.g., speakers). For example, acoustic transducers 1220(A) and/or 1220(B) may be earbuds or any other suitable type of headphone or speaker.

The configuration of acoustic transducers 1220 of the microphone array may vary. While augmented-reality system 1200 is shown in FIG. 12 as having ten acoustic transducers 1220, the number of acoustic transducers 1220 may be greater or less than ten. In some embodiments, using higher numbers of acoustic transducers 1220 may increase the amount of audio information collected and/or the sensitivity and accuracy of the audio information. In contrast, using a lower number of acoustic transducers 1220 may decrease the computing power required by an associated controller 1250 to process the collected audio information. In addition, the position of each acoustic transducer 1220 of the microphone array may vary. For example, the position of an acoustic transducer 1220 may include a defined position on the user, a defined coordinate on frame 1210, an orientation associated with each acoustic transducer 1220, or some combination thereof.

Acoustic transducers 1220(A) and 1220(B) may be positioned on different parts of the user's ear, such as behind the pinna, behind the tragus, and/or within the auricle or fossa. Or, there may be additional acoustic transducers 1220 on or surrounding the ear in addition to acoustic transducers 1220 inside the ear canal. Having an acoustic transducer 1220 positioned next to an ear canal of a user may enable the microphone array to collect information on how sounds arrive at the ear canal. By positioning at least two of acoustic transducers 1220 on either side of a user's head (e.g., as binaural microphones), augmented-reality device 1200 may simulate binaural hearing and capture a 3D stereo sound field around about a user's head. In some embodiments, acoustic transducers 1220(A) and 1220(B) may be connected to augmented-reality system 1200 via a wired connection 1230, and in other embodiments acoustic transducers 1220(A) and 1220(B) may be connected to augmented-reality system 1200 via a wireless connection (e.g., a BLUETOOTH connection). In still other embodiments, acoustic transducers 1220(A) and 1220(B) may not be used at all in conjunction with augmented-reality system 1200.

Acoustic transducers 1220 on frame 1210 may be positioned in a variety of different ways, including along the length of the temples, across the bridge, above or below display devices 1215(A) and 1215(B), or some combination thereof. Acoustic transducers 1220 may also be oriented such that the microphone array is able to detect sounds in a wide range of directions surrounding the user wearing the augmented-reality system 1200. In some embodiments, an optimization process may be performed during manufacturing of augmented-reality system 1200 to determine relative positioning of each acoustic transducer 1220 in the microphone array.

In some examples, augmented-reality system 1200 may include or be connected to an external device (e.g., a paired device), such as neckband 1205. Neckband 1205 generally represents any type or form of paired device. Thus, the following discussion of neckband 1205 may also apply to various other paired devices, such as charging cases, smart watches, smart phones, wrist bands, other wearable devices, hand-held controllers, tablet computers, laptop computers, other external compute devices, etc.

As shown, neckband 1205 may be coupled to eyewear device 1202 via one or more connectors. The connectors may be wired or wireless and may include electrical and/or non-electrical (e.g., structural) components. In some cases, eyewear device 1202 and neckband 1205 may operate independently without any wired or wireless connection between them. While FIG. 12 illustrates the components of eyewear device 1202 and neckband 1205 in example locations on eyewear device 1202 and neckband 1205, the components may be located elsewhere and/or distributed differently on eyewear device 1202 and/or neckband 1205. In some embodiments, the components of eyewear device 1202 and neckband 1205 may be located on one or more additional peripheral devices paired with eyewear device 1202, neckband 1205, or some combination thereof.

Pairing external devices, such as neckband 1205, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 1200 may be provided by a paired device or shared between a paired device and an eyewear device, thus reducing the weight, heat profile, and form factor of the eyewear device overall while still retaining desired functionality. For example, neckband 1205 may allow components that would otherwise be included on an eyewear device to be included in neckband 1205 since users may tolerate a heavier weight load on their shoulders than they would tolerate on their heads. Neckband 1205 may also have a larger surface area over which to diffuse and disperse heat to the ambient environment. Thus, neckband 1205 may allow for greater battery and computation capacity than might otherwise have been possible on a stand-alone eyewear device. Since weight carried in neckband 1205 may be less invasive to a user than weight carried in eyewear device 1202, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 1205 may be communicatively coupled with eyewear device 1202 and/or to other devices. These other devices may provide certain functions (e.g., tracking, localizing, depth mapping, processing, storage, etc.) to augmented-reality system 1200. In the embodiment of FIG. 12, neckband 1205 may include two acoustic transducers (e.g., 1220(I) and 1220(J)) that are part of the microphone array (or potentially form their own microphone subarray). Neckband 1205 may also include a controller 1225 and a power source 1235.

Acoustic transducers 1220(I) and 1220(J) of neckband 1205 may be configured to detect sound and convert the detected sound into an electronic format (analog or digital). In the embodiment of FIG. 12, acoustic transducers 1220(I) and 1220(J) may be positioned on neckband 1205, thereby increasing the distance between the neckband acoustic transducers 1220(I) and 1220(J) and other acoustic transducers 1220 positioned on eyewear device 1202. In some cases, increasing the distance between acoustic transducers 1220 of the microphone array may improve the accuracy of beamforming performed via the microphone array. For example, if a sound is detected by acoustic transducers 1220(C) and 1220(D) and the distance between acoustic transducers 1220(C) and 1220(D) is greater than, e.g., the distance between acoustic transducers 1220(D) and 1220(E), the determined source location of the detected sound may be more accurate than if the sound had been detected by acoustic transducers 1220(D) and 1220(E).

Controller 1225 of neckband 1205 may process information generated by the sensors on neckband 1205 and/or augmented-reality system 1200. For example, controller 1225 may process information from the microphone array that describes sounds detected by the microphone array. For each detected sound, controller 1225 may perform a direction-of-arrival (DOA) estimation to estimate a direction from which the detected sound arrived at the microphone array. As the microphone array detects sounds, controller 1225 may populate an audio data set with the information. In embodiments in which augmented-reality system 1200 includes an inertial measurement unit, controller 1225 may compute all inertial and spatial calculations from the IMU located on eyewear device 1202. A connector may convey information between augmented-reality system 1200 and neckband 1205 and between augmented-reality system 1200 and controller 1225. The information may be in the form of optical data, electrical data, wireless data, or any other transmittable data form. Moving the processing of information generated by augmented-reality system 1200 to neckband 1205 may reduce weight and heat in eyewear device 1202, making it more comfortable to the user.

Power source 1235 in neckband 1205 may provide power to eyewear device 1202 and/or to neckband 1205. Power source 1235 may include, without limitation, lithium-ion batteries, lithium-polymer batteries, primary lithium batteries, alkaline batteries, or any other form of power storage. In some cases, power source 1235 may be a wired power source. Including power source 1235 on neckband 1205 instead of on eyewear device 1202 may help better distribute the weight and heat generated by power source 1235.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 1300 in FIG. 13, that mostly or completely covers a user's field of view. Virtual-reality system 1300 may include a front rigid body 1302 and a band 1304 shaped to fit around a user's head. Virtual-reality system 1300 may also include output audio transducers 1306(A) and 1306(B). Furthermore, while not shown in FIG. 13, front rigid body 1302 may include one or more electronic elements, including one or more electronic displays, one or more inertial measurement units (IMUs), one or more tracking emitters or detectors, and/or any other suitable device or system for creating an artificial-reality experience.

Artificial-reality systems may include a variety of types of visual feedback mechanisms. For example, display devices in augmented-reality system 1200 and/or virtual-reality system 1300 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 1200 and/or virtual-reality system 1300 may include microLED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 1200 and/or virtual-reality system 1300 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

Some augmented-reality systems may map a user's and/or device's environment using techniques referred to as “simultaneous location and mapping” (SLAM). SLAM mapping and location identifying techniques may involve a variety of hardware and software tools that can create or update a map of an environment while simultaneously keeping track of a user's location within the mapped environment. SLAM may use many different types of sensors to create a map and determine a user's position within the map.

SLAM techniques may, for example, implement optical sensors to determine a user's location. Radios including WiFi, BLUETOOTH, global positioning system (GPS), cellular or other communication devices may be also used to determine a user's location relative to a radio transceiver or group of transceivers (e.g., a WiFi router or group of GPS satellites). Acoustic sensors such as microphone arrays or 2D or 3D sonar sensors may also be used to determine a user's location within an environment. Augmented-reality and virtual-reality devices (such as systems 1200 and 1300 of FIGS. 12 and 13, respectively) may incorporate any or all of these types of sensors to perform SLAM operations such as creating and continually updating maps of the user's current environment. In at least some of the embodiments described herein, SLAM data generated by these sensors may be referred to as “environmental data” and may indicate a user's current environment. This data may be stored in a local or remote data store (e.g., a cloud data store) and may be provided to a user's AR/VR device on demand.

When the user is wearing an augmented-reality headset or virtual-reality headset in a given environment, the user may be interacting with other users or other electronic devices that serve as audio sources. In some cases, it may be desirable to determine where the audio sources are located relative to the user and then present the audio sources to the user as if they were coming from the location of the audio source. The process of determining where the audio sources are located relative to the user may be referred to as “localization,” and the process of rendering playback of the audio source signal to appear as if it is coming from a specific direction may be referred to as “spatialization.”

Localizing an audio source may be performed in a variety of different ways. In some cases, an augmented-reality or virtual-reality headset may initiate a DOA analysis to determine the location of a sound source. The DOA analysis may include analyzing the intensity, spectra, and/or arrival time of each sound at the artificial-reality device to determine the direction from which the sounds originated. The DOA analysis may include any suitable algorithm for analyzing the surrounding acoustic environment in which the artificial-reality device is located.

For example, the DOA analysis may be designed to receive input signals from a microphone and apply digital signal processing algorithms to the input signals to estimate the direction of arrival. These algorithms may include, for example, delay and sum algorithms where the input signal is sampled, and the resulting weighted and delayed versions of the sampled signal are averaged together to determine a direction of arrival. A least mean squared (LMS) algorithm may also be implemented to create an adaptive filter. This adaptive filter may then be used to identify differences in signal intensity, for example, or differences in time of arrival. These differences may then be used to estimate the direction of arrival. In another embodiment, the DOA may be determined by converting the input signals into the frequency domain and selecting specific bins within the time-frequency (TF) domain to process. Each selected TF bin may be processed to determine whether that bin includes a portion of the audio spectrum with a direct-path audio signal. Those bins having a portion of the direct-path signal may then be analyzed to identify the angle at which a microphone array received the direct-path audio signal. The determined angle may then be used to identify the direction of arrival for the received input signal. Other algorithms not listed above may also be used alone or in combination with the above algorithms to determine DOA.

In some embodiments, different users may perceive the source of a sound as coming from slightly different locations. This may be the result of each user having a unique head-related transfer function (HRTF), which may be dictated by a user's anatomy including ear canal length and the positioning of the ear drum. The artificial-reality device may provide an alignment and orientation guide, which the user may follow to customize the sound signal presented to the user based on their unique HRTF. In some embodiments, an artificial-reality device may implement one or more microphones to listen to sounds within the user's environment. The augmented-reality or virtual-reality headset may use a variety of different array transfer functions (e.g., any of the DOA algorithms identified above) to estimate the direction of arrival for the sounds. Once the direction of arrival has been determined, the artificial-reality device may play back sounds to the user according to the user's unique HRTF. Accordingly, the DOA estimation generated using the array transfer function (ATF) may be used to determine the direction from which the sounds are to be played from. The playback sounds may be further refined based on how that specific user hears sounds according to the HRTF.

In addition to or as an alternative to performing a DOA estimation, an artificial-reality device may perform localization based on information received from other types of sensors. These sensors may include cameras, IR sensors, heat sensors, motion sensors, GPS receivers, or in some cases, sensors that detect a user's eye movements. For example, as noted above, an artificial-reality device may include an eye tracker or gaze detector that determines where the user is looking. Often, the user's eyes will look at the source of the sound, if only briefly. Such clues provided by the user's eyes may further aid in determining the location of a sound source. Other sensors such as cameras, heat sensors, and IR sensors may also indicate the location of a user, the location of an electronic device, or the location of another sound source. Any or all of the above methods may be used individually or in combination to determine the location of a sound source and may further be used to update the location of a sound source over time.

Some embodiments may implement the determined DOA to generate a more customized output audio signal for the user. For instance, an “acoustic transfer function” may characterize or define how a sound is received from a given location. More specifically, an acoustic transfer function may define the relationship between parameters of a sound at its source location and the parameters by which the sound signal is detected (e.g., detected by a microphone array or detected by a user's ear). An artificial-reality device may include one or more acoustic sensors that detect sounds within range of the device. A controller of the artificial-reality device may estimate a DOA for the detected sounds (using, e.g., any of the methods identified above) and, based on the parameters of the detected sounds, may generate an acoustic transfer function that is specific to the location of the device. This customized acoustic transfer function may thus be used to generate a spatialized output audio signal where the sound is perceived as coming from a specific location.

Indeed, once the location of the sound source or sources is known, the artificial-reality device may re-render (i.e., spatialize) the sound signals to sound as if coming from the direction of that sound source. The artificial-reality device may apply filters or other digital signal processing that alter the intensity, spectra, or arrival time of the sound signal. The digital signal processing may be applied in such a way that the sound signal is perceived as originating from the determined location. The artificial-reality device may amplify or subdue certain frequencies or change the time that the signal arrives at each ear. In some cases, the artificial-reality device may create an acoustic transfer function that is specific to the location of the device and the detected direction of arrival of the sound signal. In some embodiments, the artificial-reality device may re-render the source signal in a stereo device or multi-speaker device (e.g., a surround sound device). In such cases, separate and distinct audio signals may be sent to each speaker. Each of these audio signals may be altered according to the user's HRTF and according to measurements of the user's location and the location of the sound source to sound as if they are coming from the determined location of the sound source. Accordingly, in this manner, the artificial-reality device (or speakers associated with the device) may re-render an audio signal to sound as if originating from a specific location.

As noted, artificial-reality systems 1200 and 1300 may be used with a variety of other types of devices to provide a more compelling artificial-reality experience. These devices may be haptic interfaces with transducers that provide haptic feedback and/or that collect haptic information about a user's interaction with an environment. The artificial-reality systems disclosed herein may include various types of haptic interfaces that detect or convey various types of haptic information, including tactile feedback (e.g., feedback that a user detects via nerves in the skin, which may also be referred to as cutaneous feedback) and/or kinesthetic feedback (e.g., feedback that a user detects via receptors located in muscles, joints, and/or tendons).

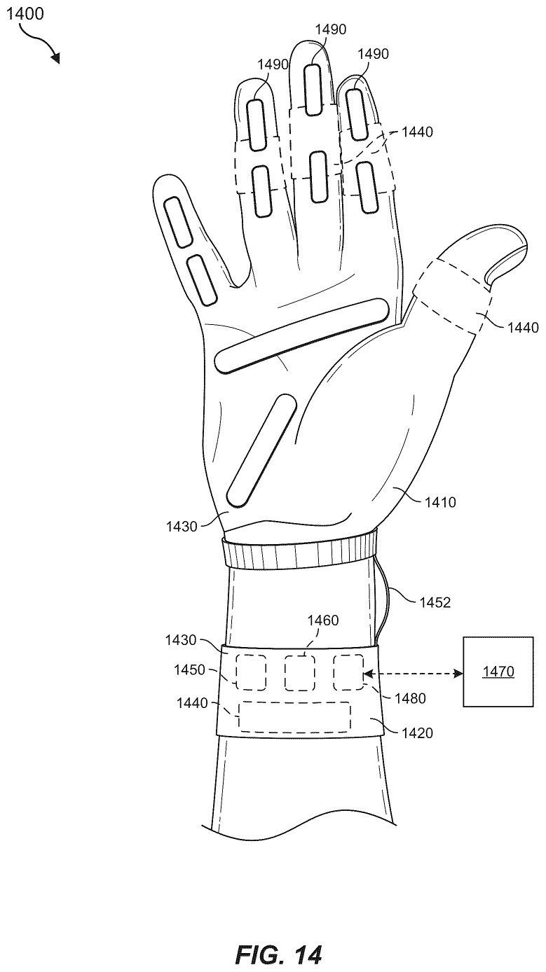

Haptic feedback may be provided by interfaces positioned within a user's environment (e.g., chairs, tables, floors, etc.) and/or interfaces on articles that may be worn or carried by a user (e.g., gloves, wristbands, etc.). As an example, FIG. 14 illustrates a vibrotactile system 1400 in the form of a wearable glove (haptic device 1410) and wristband (haptic device 1420). Haptic device 1410 and haptic device 1420 are shown as examples of wearable devices that include a flexible, wearable textile material 1430 that is shaped and configured for positioning against a user's hand and wrist, respectively. This disclosure also includes vibrotactile systems that may be shaped and configured for positioning against other human body parts, such as a finger, an arm, a head, a torso, a foot, or a leg. By way of example and not limitation, vibrotactile systems according to various embodiments of the present disclosure may also be in the form of a glove, a headband, an armband, a sleeve, a head covering, a sock, a shirt, or pants, among other possibilities. In some examples, the term “textile” may include any flexible, wearable material, including woven fabric, non-woven fabric, leather, cloth, a flexible polymer material, composite materials, etc.

One or more vibrotactile devices 1440 may be positioned at least partially within one or more corresponding pockets formed in textile material 1430 of vibrotactile system 1400. Vibrotactile devices 1440 may be positioned in locations to provide a vibrating sensation (e.g., haptic feedback) to a user of vibrotactile system 1400. For example, vibrotactile devices 1440 may be positioned against the user's finger(s), thumb, or wrist, as shown in FIG. 14. Vibrotactile devices 1440 may, in some examples, be sufficiently flexible to conform to or bend with the user's corresponding body part(s).

A power source 1450 (e.g., a battery) for applying a voltage to the vibrotactile devices 1440 for activation thereof may be electrically coupled to vibrotactile devices 1440, such as via conductive wiring 1452. In some examples, each of vibrotactile devices 1440 may be independently electrically coupled to power source 1450 for individual activation. In some embodiments, a processor 1460 may be operatively coupled to power source 1450 and configured (e.g., programmed) to control activation of vibrotactile devices 1440.

Vibrotactile system 1400 may be implemented in a variety of ways. In some examples, vibrotactile system 1400 may be a standalone system with integral subsystems and components for operation independent of other devices and systems. As another example, vibrotactile system 1400 may be configured for interaction with another device or system 1470. For example, vibrotactile system 1400 may, in some examples, include a communications interface 1480 for receiving and/or sending signals to the other device or system 1470. The other device or system 1470 may be a mobile device, a gaming console, an artificial-reality (e.g., virtual-reality, augmented-reality, mixed-reality) device, a personal computer, a tablet computer, a network device (e.g., a modem, a router, etc.), a handheld controller, etc. Communications interface 1480 may enable communications between vibrotactile system 1400 and the other device or system 1470 via a wireless (e.g., Wi-Fi, BLUETOOTH, cellular, radio, etc.) link or a wired link. If present, communications interface 1480 may be in communication with processor 1460, such as to provide a signal to processor 1460 to activate or deactivate one or more of the vibrotactile devices 1440.

Vibrotactile system 1400 may optionally include other subsystems and components, such as touch-sensitive pads 1490, pressure sensors, motion sensors, position sensors, lighting elements, and/or user interface elements (e.g., an on/off button, a vibration control element, etc.). During use, vibrotactile devices 1440 may be configured to be activated for a variety of different reasons, such as in response to the user's interaction with user interface elements, a signal from the motion or position sensors, a signal from the touch-sensitive pads 1490, a signal from the pressure sensors, a signal from the other device or system 1470, etc.

Although power source 1450, processor 1460, and communications interface 1480 are illustrated in FIG. 14 as being positioned in haptic device 1420, the present disclosure is not so limited. For example, one or more of power source 1450, processor 1460, or communications interface 1480 may be positioned within haptic device 1410 or within another wearable textile.

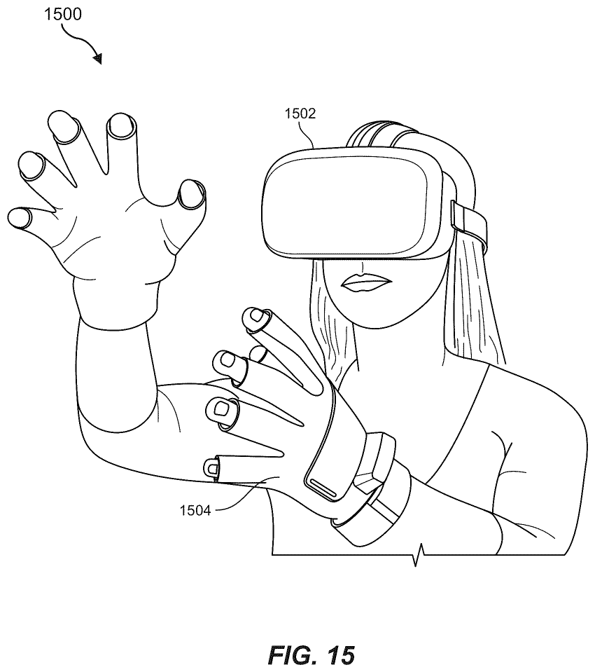

Haptic wearables, such as those shown in and described in connection with FIG. 14, may be implemented in a variety of types of artificial-reality systems and environments. FIG. 15 shows an example artificial-reality environment 1500 including one head-mounted virtual-reality display and two haptic devices (i.e., gloves), and in other embodiments any number and/or combination of these components and other components may be included in an artificial-reality system. For example, in some embodiments there may be multiple head-mounted displays each having an associated haptic device, with each head-mounted display and each haptic device communicating with the same console, portable computing device, or other computing system.

Head-mounted display 1502 generally represents any type or form of virtual-reality system, such as virtual-reality system 1300 in FIG. 13. Haptic device 1504 generally represents any type or form of wearable device, worn by a user of an artificial-reality system, that provides haptic feedback to the user to give the user the perception that he or she is physically engaging with a virtual object. In some embodiments, haptic device 1504 may provide haptic feedback by applying vibration, motion, and/or force to the user. For example, haptic device 1504 may limit or augment a user's movement. To give a specific example, haptic device 1504 may limit a user's hand from moving forward so that the user has the perception that his or her hand has come in physical contact with a virtual wall. In this specific example, one or more actuators within the haptic device may achieve the physical-movement restriction by pumping fluid into an inflatable bladder of the haptic device. In some examples, a user may also use haptic device 1504 to send action requests to a console. Examples of action requests include, without limitation, requests to start an application and/or end the application and/or requests to perform a particular action within the application.

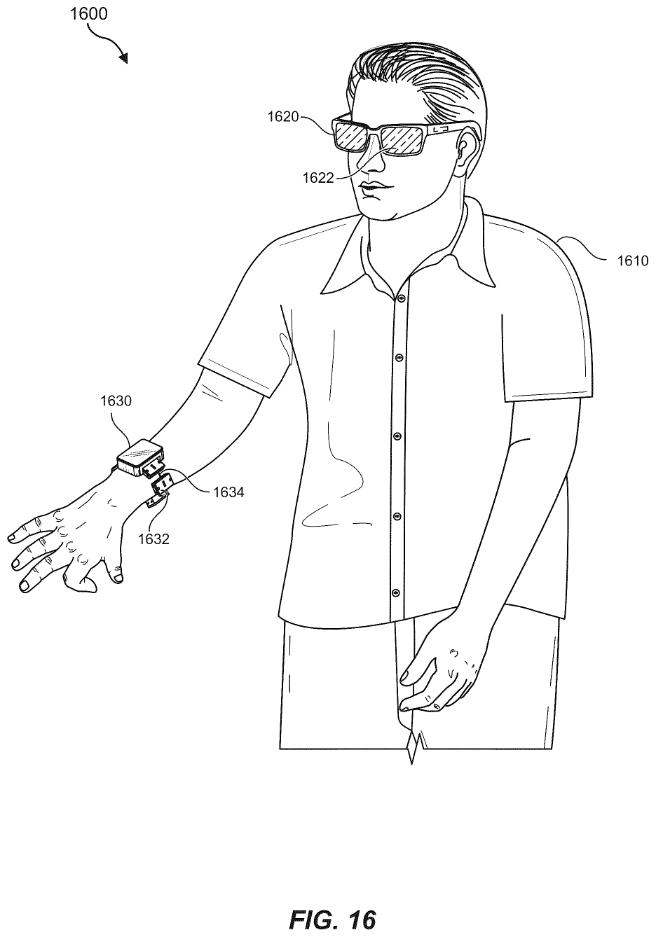

While haptic interfaces may be used with virtual-reality systems, as shown in FIG. 15, haptic interfaces may also be used with augmented-reality systems, as shown in FIG. 16. FIG. 16 is a perspective view of a user 1610 interacting with an augmented-reality system 1600. In this example, user 1610 may wear a pair of augmented-reality glasses 1620 that may have one or more displays 1622 and that are paired with a haptic device 1630. In this example, haptic device 1630 may be a wristband that includes a plurality of band elements 1632 and a tensioning mechanism 1634 that connects band elements 1632 to one another.

One or more of band elements 1632 may include any type or form of actuator suitable for providing haptic feedback. For example, one or more of band elements 1632 may be configured to provide one or more of various types of cutaneous feedback, including vibration, force, traction, texture, and/or temperature. To provide such feedback, band elements 1632 may include one or more of various types of actuators. In one example, each of band elements 1632 may include a vibrotactor (e.g., a vibrotactile actuator) configured to vibrate in unison or independently to provide one or more of various types of haptic sensations to a user. Alternatively, only a single band element or a subset of band elements may include vibrotactors.

Haptic devices 1410, 1420, 1504, and 1630 may include any suitable number and/or type of haptic transducer, sensor, and/or feedback mechanism. For example, haptic devices 1410, 1420, 1504, and 1630 may include one or more mechanical transducers, piezoelectric transducers, and/or fluidic transducers. Haptic devices 1410, 1420, 1504, and 1630 may also include various combinations of different types and forms of transducers that work together or independently to enhance a user's artificial-reality experience. In one example, each of band elements 1632 of haptic device 1630 may include a vibrotactor (e.g., a vibrotactile actuator) configured to vibrate in unison or independently to provide one or more of various types of haptic sensations to a user.

In some embodiments, the systems described herein may also include an eye-tracking subsystem designed to identify and track various characteristics of a user's eye(s), such as the user's gaze direction. The phrase “eye tracking” may, in some examples, refer to a process by which the position, orientation, and/or motion of an eye is measured, detected, sensed, determined, and/or monitored. The disclosed systems may measure the position, orientation, and/or motion of an eye in a variety of different ways, including through the use of various optical-based eye-tracking techniques, ultrasound-based eye-tracking techniques, etc. An eye-tracking subsystem may be configured in a number of different ways and may include a variety of different eye-tracking hardware components or other computer-vision components. For example, an eye-tracking subsystem may include a variety of different optical sensors, such as two-dimensional (2D) or 3D cameras, time-of-flight depth sensors, single-beam or sweeping laser rangefinders, 3D LiDAR sensors, and/or any other suitable type or form of optical sensor. In this example, a processing subsystem may process data from one or more of these sensors to measure, detect, determine, and/or otherwise monitor the position, orientation, and/or motion of the user's eye(s).

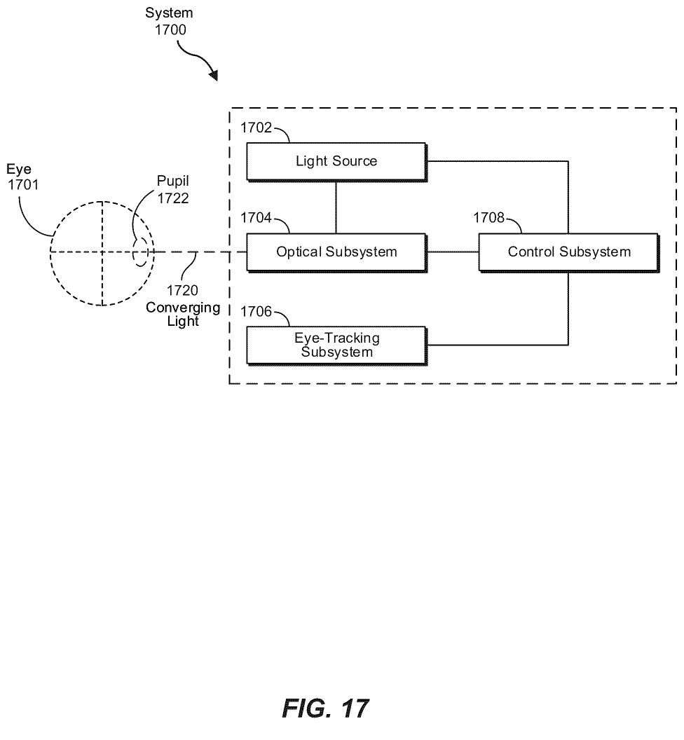

FIG. 17 is an illustration of an exemplary system 1700 that incorporates an eye-tracking subsystem capable of tracking a user's eye(s). As depicted in FIG. 17, system 1700 may include a light source 1702, an optical subsystem 1704, an eye-tracking subsystem 1706, and/or a control subsystem 1708. In some examples, light source 1702 may generate light for an image (e.g., to be presented to an eye 1701 of the viewer). Light source 1702 may represent any of a variety of suitable devices. For example, light source 1702 can include a two-dimensional projector (e.g., a LCOS display), a scanning source (e.g., a scanning laser), or other device (e.g., an LCD, an LED display, an OLED display, an active-matrix OLED display (AMOLED), a transparent OLED display (TOLED), a waveguide, or some other display capable of generating light for presenting an image to the viewer). In some examples, the image may represent a virtual image, which may refer to an optical image formed from the apparent divergence of light rays from a point in space, as opposed to an image formed from the light ray's actual divergence.

In some embodiments, optical subsystem 1704 may receive the light generated by light source 1702 and generate, based on the received light, converging light 1720 that includes the image. In some examples, optical subsystem 1704 may include any number of lenses (e.g., Fresnel lenses, convex lenses, concave lenses), apertures, filters, mirrors, prisms, and/or other optical components, possibly in combination with actuators and/or other devices. In particular, the actuators and/or other devices may translate and/or rotate one or more of the optical components to alter one or more aspects of converging light 1720. Further, various mechanical couplings may serve to maintain the relative spacing and/or the orientation of the optical components in any suitable combination.

In one embodiment, eye-tracking subsystem 1706 may generate tracking information indicating a gaze angle of an eye 1701 of the viewer. In this embodiment, control subsystem 1708 may control aspects of optical subsystem 1704 (e.g., the angle of incidence of converging light 1720) based at least in part on this tracking information. Additionally, in some examples, control subsystem 1708 may store and utilize historical tracking information (e.g., a history of the tracking information over a given duration, such as the previous second or fraction thereof) to anticipate the gaze angle of eye 1701 (e.g., an angle between the visual axis and the anatomical axis of eye 1701). In some embodiments, eye-tracking subsystem 1706 may detect radiation emanating from some portion of eye 1701 (e.g., the cornea, the iris, the pupil, or the like) to determine the current gaze angle of eye 1701. In other examples, eye-tracking subsystem 1706 may employ a wavefront sensor to track the current location of the pupil.

Any number of techniques can be used to track eye 1701. Some techniques may involve illuminating eye 1701 with infrared light and measuring reflections with at least one optical sensor that is tuned to be sensitive to the infrared light. Information about how the infrared light is reflected from eye 1701 may be analyzed to determine the position(s), orientation(s), and/or motion(s) of one or more eye feature(s), such as the cornea, pupil, iris, and/or retinal blood vessels.

In some examples, the radiation captured by a sensor of eye-tracking subsystem 1706 may be digitized (i.e., converted to an electronic signal). Further, the sensor may transmit a digital representation of this electronic signal to one or more processors (for example, processors associated with a device including eye-tracking subsystem 1706). Eye-tracking subsystem 1706 may include any of a variety of sensors in a variety of different configurations. For example, eye-tracking subsystem 1706 may include an infrared detector that reacts to infrared radiation. The infrared detector may be a thermal detector, a photonic detector, and/or any other suitable type of detector. Thermal detectors may include detectors that react to thermal effects of the incident infrared radiation.

In some examples, one or more processors may process the digital representation generated by the sensor(s) of eye-tracking subsystem 1706 to track the movement of eye 1701. In another example, these processors may track the movements of eye 1701 by executing algorithms represented by computer-executable instructions stored on non-transitory memory. In some examples, on-chip logic (e.g., an application-specific integrated circuit or ASIC) may be used to perform at least portions of such algorithms. As noted, eye-tracking subsystem 1706 may be programmed to use an output of the sensor(s) to track movement of eye 1701. In some embodiments, eye-tracking subsystem 1706 may analyze the digital representation generated by the sensors to extract eye rotation information from changes in reflections. In one embodiment, eye-tracking subsystem 1706 may use corneal reflections or glints (also known as Purkinje images) and/or the center of the eye's pupil 1722 as features to track over time.

In some embodiments, eye-tracking subsystem 1706 may use the center of the eye's pupil 1722 and infrared or near-infrared, non-collimated light to create corneal reflections. In these embodiments, eye-tracking subsystem 1706 may use the vector between the center of the eye's pupil 1722 and the corneal reflections to compute the gaze direction of eye 1701. In some embodiments, the disclosed systems may perform a calibration procedure for an individual (using, e.g., supervised or unsupervised techniques) before tracking the user's eyes. For example, the calibration procedure may include directing users to look at one or more points displayed on a display while the eye-tracking system records the values that correspond to each gaze position associated with each point.

In some embodiments, eye-tracking subsystem 1706 may use two types of infrared and/or near-infrared (also known as active light) eye-tracking techniques: bright-pupil and dark-pupil eye tracking, which may be differentiated based on the location of an illumination source with respect to the optical elements used. If the illumination is coaxial with the optical path, then eye 1701 may act as a retroreflector as the light reflects off the retina, thereby creating a bright pupil effect similar to a red-eye effect in photography. If the illumination source is offset from the optical path, then the eye's pupil 1722 may appear dark because the retroreflection from the retina is directed away from the sensor. In some embodiments, bright-pupil tracking may create greater iris/pupil contrast, allowing more robust eye tracking with iris pigmentation, and may feature reduced interference (e.g., interference caused by eyelashes and other obscuring features). Bright-pupil tracking may also allow tracking in lighting conditions ranging from total darkness to a very bright environment.

In some embodiments, control subsystem 1708 may control light source 1702 and/or optical subsystem 1704 to reduce optical aberrations (e.g., chromatic aberrations and/or monochromatic aberrations) of the image that may be caused by or influenced by eye 1701. In some examples, as mentioned above, control subsystem 1708 may use the tracking information from eye-tracking subsystem 1706 to perform such control. For example, in controlling light source 1702, control subsystem 1708 may alter the light generated by light source 1702 (e.g., by way of image rendering) to modify (e.g., pre-distort) the image so that the aberration of the image caused by eye 1701 is reduced.

The disclosed systems may track both the position and relative size of the pupil (since, e.g., the pupil dilates and/or contracts). In some examples, the eye-tracking devices and components (e.g., sensors and/or sources) used for detecting and/or tracking the pupil may be different (or calibrated differently) for different types of eyes. For example, the frequency range of the sensors may be different (or separately calibrated) for eyes of different colors and/or different pupil types, sizes, and/or the like. As such, the various eye-tracking components (e.g., infrared sources and/or sensors) described herein may need to be calibrated for each individual user and/or eye.

The disclosed systems may track both eyes with and without ophthalmic correction, such as that provided by contact lenses worn by the user. In some embodiments, ophthalmic correction elements (e.g., adjustable lenses) may be directly incorporated into the artificial reality systems described herein. In some examples, the color of the user's eye may necessitate modification of a corresponding eye-tracking algorithm. For example, eye-tracking algorithms may need to be modified based at least in part on the differing color contrast between a brown eye and, for example, a blue eye.

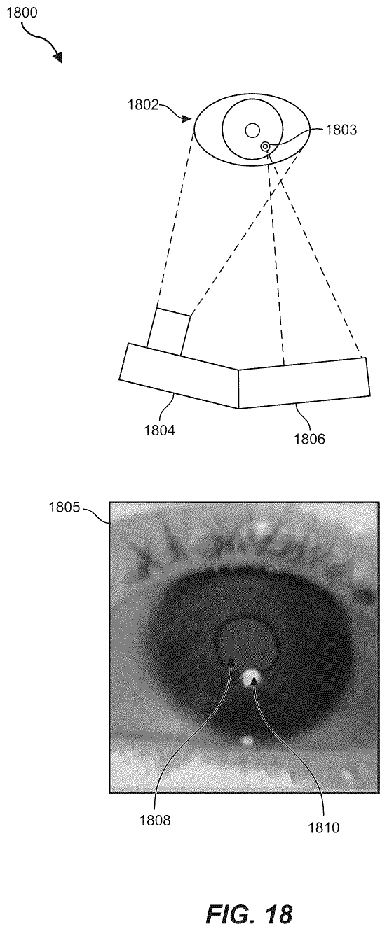

FIG. 18 is a more detailed illustration of various aspects of the eye-tracking subsystem illustrated in FIG. 17. As shown in this figure, an eye-tracking subsystem 1800 may include at least one source 1804 and at least one sensor 1806. Source 1804 generally represents any type or form of element capable of emitting radiation. In one example, source 1804 may generate visible, infrared, and/or near-infrared radiation. In some examples, source 1804 may radiate non-collimated infrared and/or near-infrared portions of the electromagnetic spectrum towards an eye 1802 of a user. Source 1804 may utilize a variety of sampling rates and speeds. For example, the disclosed systems may use sources with higher sampling rates in order to capture fixational eye movements of a user's eye 1802 and/or to correctly measure saccade dynamics of the user's eye 1802. As noted above, any type or form of eye-tracking technique may be used to track the user's eye 1802, including optical-based eye-tracking techniques, ultrasound-based eye-tracking techniques, etc.

Sensor 1806 generally represents any type or form of element capable of detecting radiation, such as radiation reflected off the user's eye 1802. Examples of sensor 1806 include, without limitation, a charge coupled device (CCD), a photodiode array, a complementary metal-oxide-semiconductor (CMOS) based sensor device, and/or the like. In one example, sensor 1806 may represent a sensor having predetermined parameters, including, but not limited to, a dynamic resolution range, linearity, and/or other characteristic selected and/or designed specifically for eye tracking.

As detailed above, eye-tracking subsystem 1800 may generate one or more glints. As detailed above, a glint 1803 may represent reflections of radiation (e.g., infrared radiation from an infrared source, such as source 1804) from the structure of the user's eye. In various embodiments, glint 1803 and/or the user's pupil may be tracked using an eye-tracking algorithm executed by a processor (either within or external to an artificial reality device). For example, an artificial reality device may include a processor and/or a memory device in order to perform eye tracking locally and/or a transceiver to send and receive the data necessary to perform eye tracking on an external device (e.g., a mobile phone, cloud server, or other computing device).

FIG. 18 shows an example image 1805 captured by an eye-tracking subsystem, such as eye-tracking subsystem 1800. In this example, image 1805 may include both the user's pupil 1808 and a glint 1810 near the same. In some examples, pupil 1808 and/or glint 1810 may be identified using an artificial-intelligence-based algorithm, such as a computer-vision-based algorithm. In one embodiment, image 1805 may represent a single frame in a series of frames that may be analyzed continuously in order to track the eye 1802 of the user. Further, pupil 1808 and/or glint 1810 may be tracked over a period of time to determine a user's gaze.

In one example, eye-tracking subsystem 1800 may be configured to identify and measure the inter-pupillary distance (IPD) of a user. In some embodiments, eye-tracking subsystem 1800 may measure and/or calculate the IPD of the user while the user is wearing the artificial reality system. In these embodiments, eye-tracking subsystem 1800 may detect the positions of a user's eyes and may use this information to calculate the user's IPD.

As noted, the eye-tracking systems or subsystems disclosed herein may track a user's eye position and/or eye movement in a variety of ways. In one example, one or more light sources and/or optical sensors may capture an image of the user's eyes. The eye-tracking subsystem may then use the captured information to determine the user's inter-pupillary distance, interocular distance, and/or a 3D position of each eye (e.g., for distortion adjustment purposes), including a magnitude of torsion and rotation (i.e., roll, pitch, and yaw) and/or gaze directions for each eye. In one example, infrared light may be emitted by the eye-tracking subsystem and reflected from each eye. The reflected light may be received or detected by an optical sensor and analyzed to extract eye rotation data from changes in the infrared light reflected by each eye.

The eye-tracking subsystem may use any of a variety of different methods to track the eyes of a user. For example, a light source (e.g., infrared light-emitting diodes) may emit a dot pattern onto each eye of the user. The eye-tracking subsystem may then detect (e.g., via an optical sensor coupled to the artificial reality system) and analyze a reflection of the dot pattern from each eye of the user to identify a location of each pupil of the user. Accordingly, the eye-tracking subsystem may track up to six degrees of freedom of each eye (i.e., 3D position, roll, pitch, and yaw) and at least a subset of the tracked quantities may be combined from two eyes of a user to estimate a gaze point (i.e., a 3D location or position in a virtual scene where the user is looking) and/or an IPD.

In some cases, the distance between a user's pupil and a display may change as the user's eye moves to look in different directions. The varying distance between a pupil and a display as viewing direction changes may be referred to as “pupil swim” and may contribute to distortion perceived by the user as a result of light focusing in different locations as the distance between the pupil and the display changes. Accordingly, measuring distortion at different eye positions and pupil distances relative to displays and generating distortion corrections for different positions and distances may allow mitigation of distortion caused by pupil swim by tracking the 3D position of a user's eyes and applying a distortion correction corresponding to the 3D position of each of the user's eyes at a given point in time. Thus, knowing the 3D position of each of a user's eyes may allow for the mitigation of distortion caused by changes in the distance between the pupil of the eye and the display by applying a distortion correction for each 3D eye position. Furthermore, as noted above, knowing the position of each of the user's eyes may also enable the eye-tracking subsystem to make automated adjustments for a user's IPD.

In some embodiments, a display subsystem may include a variety of additional subsystems that may work in conjunction with the eye-tracking subsystems described herein. For example, a display subsystem may include a varifocal subsystem, a scene-rendering module, and/or a vergence-processing module. The varifocal subsystem may cause left and right display elements to vary the focal distance of the display device. In one embodiment, the varifocal subsystem may physically change the distance between a display and the optics through which it is viewed by moving the display, the optics, or both. Additionally, moving or translating two lenses relative to each other may also be used to change the focal distance of the display. Thus, the varifocal subsystem may include actuators or motors that move displays and/or optics to change the distance between them. This varifocal subsystem may be separate from or integrated into the display subsystem. The varifocal subsystem may also be integrated into or separate from its actuation subsystem and/or the eye-tracking subsystems described herein.

In one example, the display subsystem may include a vergence-processing module configured to determine a vergence depth of a user's gaze based on a gaze point and/or an estimated intersection of the gaze lines determined by the eye-tracking subsystem. Vergence may refer to the simultaneous movement or rotation of both eyes in opposite directions to maintain single binocular vision, which may be naturally and automatically performed by the human eye. Thus, a location where a user's eyes are verged is where the user is looking and is also typically the location where the user's eyes are focused. For example, the vergence-processing module may triangulate gaze lines to estimate a distance or depth from the user associated with intersection of the gaze lines. The depth associated with intersection of the gaze lines may then be used as an approximation for the accommodation distance, which may identify a distance from the user where the user's eyes are directed. Thus, the vergence distance may allow for the determination of a location where the user's eyes should be focused and a depth from the user's eyes at which the eyes are focused, thereby providing information (such as an object or plane of focus) for rendering adjustments to the virtual scene.

The vergence-processing module may coordinate with the eye-tracking subsystems described herein to make adjustments to the display subsystem to account for a user's vergence depth. When the user is focused on something at a distance, the user's pupils may be slightly farther apart than when the user is focused on something close. The eye-tracking subsystem may obtain information about the user's vergence or focus depth and may adjust the display subsystem to be closer together when the user's eyes focus or verge on something close and to be farther apart when the user's eyes focus or verge on something at a distance.

The eye-tracking information generated by the above-described eye-tracking subsystems may also be used, for example, to modify various aspect of how different computer-generated images are presented. For example, a display subsystem may be configured to modify, based on information generated by an eye-tracking subsystem, at least one aspect of how the computer-generated images are presented. For instance, the computer-generated images may be modified based on the user's eye movement, such that if a user is looking up, the computer-generated images may be moved upward on the screen. Similarly, if the user is looking to the side or down, the computer-generated images may be moved to the side or downward on the screen. If the user's eyes are closed, the computer-generated images may be paused or removed from the display and resumed once the user's eyes are back open.

The above-described eye-tracking subsystems can be incorporated into one or more of the various artificial reality systems described herein in a variety of ways. For example, one or more of the various components of system 1700 and/or eye-tracking subsystem 1800 may be incorporated into augmented-reality system 1200 in FIG. 12 and/or virtual-reality system 1300 in FIG. 13 to enable these systems to perform various eye-tracking tasks (including one or more of the eye-tracking operations described herein).

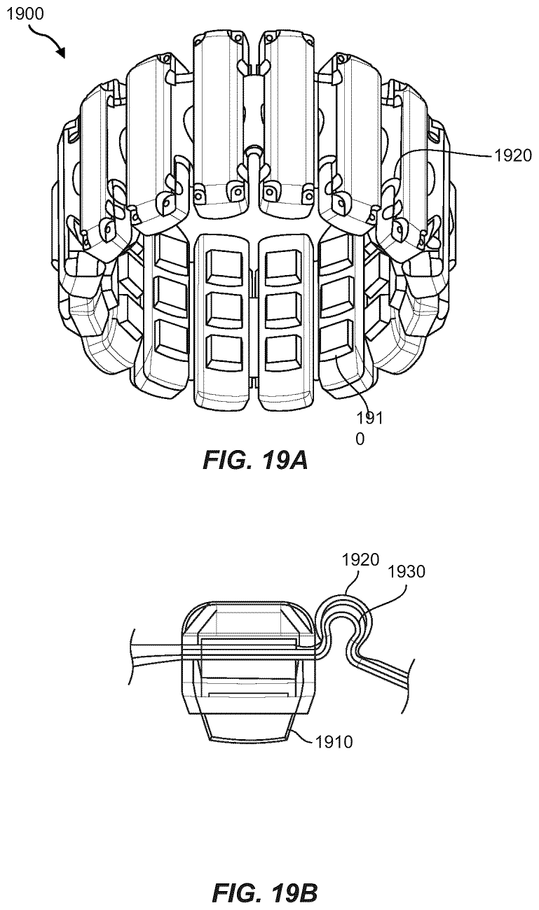

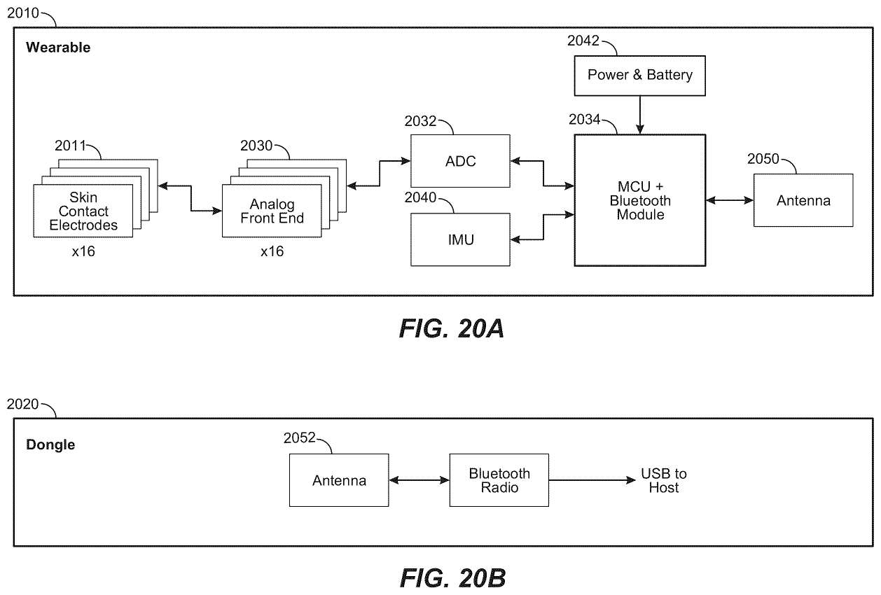

FIG. 19A illustrates an exemplary human-machine interface (also referred to herein as an EMG control interface) configured to be worn around a user's lower arm or wrist as a wearable system 1900. In this example, wearable system 1900 may include sixteen neuromuscular sensors 1910 (e.g., EMG sensors) arranged circumferentially around an elastic band 1920 with an interior surface 1930 configured to contact a user's skin. However, any suitable number of neuromuscular sensors may be used. The number and arrangement of neuromuscular sensors may depend on the particular application for which the wearable device is used. For example, a wearable armband or wristband can be used to generate control information for controlling an augmented reality system, a robot, controlling a vehicle, scrolling through text, controlling a virtual avatar, or any other suitable control task. As shown, the sensors may be coupled together using flexible electronics incorporated into the wireless device. FIG. 19B illustrates a cross-sectional view through one of the sensors of the wearable device shown in FIG. 19A. In some embodiments, the output of one or more of the sensing components can be optionally processed using hardware signal processing circuitry (e.g., to perform amplification, filtering, and/or rectification). In other embodiments, at least some signal processing of the output of the sensing components can be performed in software. Thus, signal processing of signals sampled by the sensors can be performed in hardware, software, or by any suitable combination of hardware and software, as aspects of the technology described herein are not limited in this respect. A non-limiting example of a signal processing chain used to process recorded data from sensors 1910 is discussed in more detail below with reference to FIGS. 20A and 20B.

FIGS. 20A and 20B illustrate an exemplary schematic diagram with internal components of a wearable system with EMG sensors. As shown, the wearable system may include a wearable portion 2010 (FIG. 20A) and a dongle portion 2020 (FIG. 20B) in communication with the wearable portion 2010 (e.g., via BLUETOOTH or another suitable wireless communication technology). As shown in FIG. 20A, the wearable portion 2010 may include skin contact electrodes 2011, examples of which are described in connection with FIGS. 19A and 19B. The output of the skin contact electrodes 2011 may be provided to analog front end 2030, which may be configured to perform analog processing (e.g., amplification, noise reduction, filtering, etc.) on the recorded signals. The processed analog signals may then be provided to analog-to-digital converter 2032, which may convert the analog signals to digital signals that can be processed by one or more computer processors. An example of a computer processor that may be used in accordance with some embodiments is microcontroller (MCU) 2034, illustrated in FIG. 20A. As shown, MCU 2034 may also include inputs from other sensors (e.g., IMU sensor 2040), and power and battery module 2042. The output of the processing performed by MCU 2034 may be provided to antenna 2050 for transmission to dongle portion 2020 shown in FIG. 20B.

Dongle portion 2020 may include antenna 2052, which may be configured to communicate with antenna 2050 included as part of wearable portion 2010. Communication between antennas 2050 and 2052 may occur using any suitable wireless technology and protocol, non-limiting examples of which include radiofrequency signaling and BLUETOOTH. As shown, the signals received by antenna 2052 of dongle portion 2020 may be provided to a host computer for further processing, display, and/or for effecting control of a particular physical or virtual object or objects.

Although the examples provided with reference to FIGS. 19A-19B and FIGS. 20A-20B are discussed in the context of interfaces with EMG sensors, the techniques described herein for reducing electromagnetic interference can also be implemented in wearable interfaces with other types of sensors including, but not limited to, mechanomyography (MMG) sensors, sonomyography (SMG) sensors, and electrical impedance tomography (EIT) sensors. The techniques described herein for reducing electromagnetic interference can also be implemented in wearable interfaces that communicate with computer hosts through wires and cables (e.g., USB cables, optical fiber cables, etc.).

As detailed above, the computing devices and systems described and/or illustrated herein broadly represent any type or form of computing device or system capable of executing computer-readable instructions, such as those contained within the modules described herein. In their most basic configuration, these computing device(s) may each include at least one memory device and at least one physical processor.

In some examples, the term “memory device” generally refers to any type or form of volatile or non-volatile storage device or medium capable of storing data and/or computer-readable instructions. In one example, a memory device may store, load, and/or maintain one or more of the modules described herein. Examples of memory devices include, without limitation, Random Access Memory (RAM), Read Only Memory (ROM), flash memory, Hard Disk Drives (HDDs), Solid-State Drives (SSDs), optical disk drives, caches, variations or combinations of one or more of the same, or any other suitable storage memory.

In some examples, the term “physical processor” generally refers to any type or form of hardware-implemented processing unit capable of interpreting and/or executing computer-readable instructions. In one example, a physical processor may access and/or modify one or more modules stored in the above-described memory device. Examples of physical processors include, without limitation, microprocessors, microcontrollers, Central Processing Units (CPUs), Field-Programmable Gate Arrays (FPGAs) that implement softcore processors, Application-Specific Integrated Circuits (ASICs), portions of one or more of the same, variations or combinations of one or more of the same, or any other suitable physical processor.

Although illustrated as separate elements, the modules described and/or illustrated herein may represent portions of a single module or application. In addition, in certain embodiments one or more of these modules may represent one or more software applications or programs that, when executed by a computing device, may cause the computing device to perform one or more tasks. For example, one or more of the modules described and/or illustrated herein may represent modules stored and configured to run on one or more of the computing devices or systems described and/or illustrated herein. One or more of these modules may also represent all or portions of one or more special-purpose computers configured to perform one or more tasks.

In addition, one or more of the modules described herein may transform data, physical devices, and/or representations of physical devices from one form to another. For example, one or more of the modules recited herein may transform a processor, volatile memory, non-volatile memory, and/or any other portion of a physical computing device from one form to another by executing on the computing device, storing data on the computing device, and/or otherwise interacting with the computing device.

In some embodiments, the term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A device comprising:
a die-to-die interconnect, comprising:
a first module configured to convert data from a first synchronous domain to a dual-rail quasi-delay-insensitive format; and
a second module configured to convert the data from the dual-rail quasi-delay-insensitive format to a second synchronous domain.

2. The device of claim 1, wherein the first module and the second module are coupled by hybrid bonding.

3. The device of claim 1, wherein the first module comprises:
a first bisynchronous First-In First-Out (FIFO) buffer;
a first weak-conditioned half-buffer (WCHB) layer; and
a first converter configured to read from the first bisynchronous FIFO buffer and write to the first WCHB layer.

4. The device of claim 3, wherein the first bisynchronous FIFO buffer is configured to:
be written to according to a clock of the first synchronous domain; and
be read from based on an acknowledgement signal from the first WCHB layer.

5. The device of claim 3, wherein:
the first module receives the data via an n-bit bus; and
the first WCHB layer comprises n WCHBs operating in parallel.

6. The device of claim 3, wherein the first converter is configured to pop the data from the first FIFO buffer when the data is consumed.

7. The device of claim 1, wherein the second module comprises:
a second WCHB layer;
a second bisynchronous FIFO buffer; and
a second converter configured to read from the second WCHB layer and write to the second FIFO buffer.

8. The device of claim 7, wherein the second bisynchronous FIFO buffer is configured to:
be written to based on an acknowledgement signal from the second WCHB layer; and
be read from according to a clock of the second synchronous domain.

9. The device of claim 7, wherein:
the second module provides the data via an n-bit bus; and
the second WCHB layer comprises n WCHBs operating in parallel.

10. The device of claim 1, wherein the first synchronous domain and the second synchronous domain are a same domain.

11. A system comprising:
a first die stacked with a second die; and
a die-to-die interconnect connecting the first die and the second die, comprising:
a first module configured to convert data from a first synchronous domain of the first die to a dual-rail quasi-delay-insensitive format; and
a second module configured to convert the data from the dual-rail quasi-delay-insensitive format to a second synchronous domain of the second die.

12. The system of claim 11, wherein the first module and the second module are coupled by hybrid bonding.

13. The system of claim 11, wherein the first module comprises:
a first bisynchronous First-In First-Out (FIFO) buffer;
a first weak-conditioned half-buffer (WCHB) layer; and
a first converter configured to read from the first bisynchronous FIFO buffer and write to the first WCHB layer.

14. The system of claim 13, wherein the first bisynchronous FIFO buffer is configured to:
be written to according to a clock of the first synchronous domain; and
be read from based on an acknowledgement signal from the first WCHB layer.

15. The system of claim 13, wherein:
the first module receives the data via an n-bit bus; and
the first WCHB layer comprises n WCHBs operating in parallel.

16. The system of claim 13, wherein the first converter is configured to pop the data from the first FIFO buffer when the data is consumed.

17. The system of claim 11, wherein the second module comprises:
a second WCHB layer;
a second bisynchronous FIFO buffer; and
a second converter configured to read from the second WCHB layer and write to the second FIFO buffer.

18. The system of claim 17, wherein the second bisynchronous FIFO buffer is configured to:
be written to based on an acknowledgement signal from the second WCHB layer; and
be read from according to a clock of the second synchronous domain.

19. The system of claim 17, wherein:
the second module provides the data via an n-bit bus; and
the second WCHB layer comprises n WCHBs operating in parallel.

20. A method of manufacture comprising:
stacking a first die with a second die, at least in part by forming a die-to-die interconnect between the first die and the second die, wherein forming the die-to-die interconnect comprises forming a hybrid bond between a first module of the first die and a second module of the second die, wherein:
the first module is configured to convert data from a first synchronous domain of the first die to a dual-rail quasi-delay-insensitive format; and
the second module is configured to convert the data from the dual-rail quasi-delay-insensitive format to a second synchronous domain of the second die.
